(19) United States
(12) Patent Application Publication
(10) Pub. No.: US 2005/0173792 A1
(43) Pub. Date: Aug. 11, 2005

(54) Structure for isolating thermal interface material

(75) Inventors: Young-Kwang Sheu, Bade City (TW); Fu-Chien Yu, Sinjhuang City (TW); Hung-Ming Lin, Yogh City (TW); Chia-Tseng Huang, Taipei City (TW)

Correspondence Address: NIKOLAI & MERSEREAU, P.A., 900 SECOND AVENUE SOUTH, SUITE 820, MINNEAPOLIS, MN, 55402, US

(73) Assignee: UNIWILL COMPUTER CORP., Chungli City (TW)

(21) Appl. No.: 11/039,725

(22) Filed: Jan. 19, 2005

(30) Foreign Application Priority Data
Feb. 10, 2004 (TW) 093201892

(51) Int. Cl. H01L 29/76

(52) U.S. Cl. 257/717

(57) ABSTRACT

A structure for isolating thermal interface material includes an isolating element and a heat dissipating element. The isolating element is hollow to encompass a heat generating element. With compression of the heat dissipating element on the heat generating element, thermal interface material between them is limited to flow within the closed room between the isolation element and heat generating element. The heat dissipating element further has a bump exactly contacting the heat generating element and a little smaller than the hollow portion of the isolating element. Therefore, the thermal interface material would not overflow while changing from solid phase to a gel or a liquid phase caused by raising temperature of the heat generating element, and the contamination or short circuits can be prevented.

### BACKGROUND OF THE INVENTION

1. Field of the Invention

The present invention relates to a structure for isolating thermal interface material, especially to a structure for preventing thermal interface melted by high temperature from spreading out to cause environmental pollution or an electrical short.

2. Description of Related Art

Electrical components generating high heat energy while running are generally called heat generating element, such as CPU, power IC, etc. For a safe performance of the heat generating element under a critical temperature the heat generating element can stand, operator adds a heat dissipating element, such as heat sink, on the heat generating element surface for dissipating heat. On the heat dissipating element a cooling fan is mounted to rapidly cool the heat generating element.

Between a heat generating element and a heat dissipating element, there usually exists a thermal interface material (TIM). The thermal interface material is normally a phase-changing material, thermal grease etc. However, using thermal interface material causes some problems. When the thermal interface material is changed from a solid phase to a gel phase or even a liquid phase by heating process, the thermal interface material in gel phase or liquid phase is possible to spread and pollute nearby components. This will easily cause an electrical short.

In order to solve above-mentioned problem, an isolating apparatus has been created as shown in FIG. 1. The isolating apparatus includes an isolating element (20A), a heat dissipating element (30A) and a thermal interface material (40A). The isolating element (20A) surrounds a heat generating element (10A) set on a printed circuit board (PCB) (11A) and is sandwiched between the heat dissipating element (30A) and the PCB (11A). An enclosed room is defined by the combination of the isolating element (20A), the heat dissipating element (30A) and the PCB (11A) for preventing the thermal interface material (40A) coated on the top face of the heat generating element (10A) from overflowing the enclosed room. However, because the isolating element (20A) has to be pressed heavily to ensure the room completely enclosed, it is often seen that the isolating element (20A) is overly pressed so that the isolating element (20A) expands outward to reduce the enclosed room volume such that the melted thermal interface material (40A) is possible to overflow the isolating element (20A).

### SUMMARY OF THE INVENTION

The primary objective of the present invention is to provide a structure for isolating thermal interface material. The structure has an isolating element wrapping around a heat generating element set on a substrate and is sandwiched between the substrate and a heat dissipating element such that the structure is able to restrict thermal interface material existing between the heating generating element and the heat dissipating element to flow in a closed room defined by the combination of the heat dissipating element, isolating element and the heat generating element. Besides, a bump slightly smaller than the isolating element is formed on a bottom face of the heat dissipating element so that the thermal interface material will not overflow everywhere to cause pollution, short circuits and even danger while the thermal interface material have changed from solid phase to gel phase or liquid phase.

A different objective of the present invention is that the isolating element of the structure for isolating thermal interface material has suitable flexibility to be lengthened while being pressed by the heat dissipating element such that the isolating element is able to tightly sandwiched between the heat dissipating element and the substrate so as to prevent the thermal interface material from overflowing the isolating element. The isolating element is made of porous material to enhance escape of vapor that remains in the thermal interface material.

Other and further features, advantages and benefits of the invention will become apparent in the following description taken in conjunction with the following drawings. It is to be understood that the foregoing general description and following detailed description are exemplary and explanatory but are not to be restrictive of the invention. The accompanying drawings are incorporated in and constitute a part of this application and, together with the description, serve to explain the principles of the invention in general terms. Like numerals refer to like parts throughout the disclosure.

### BRIEF DESCRIPTION OF THE DRAWINGS

The objects, spirits and advantages of the preferred embodiments of the present invention will be readily understood by the accompanying drawings and detailed descriptions, wherein:

FIG. 1 is a cross sectional view of prior art;

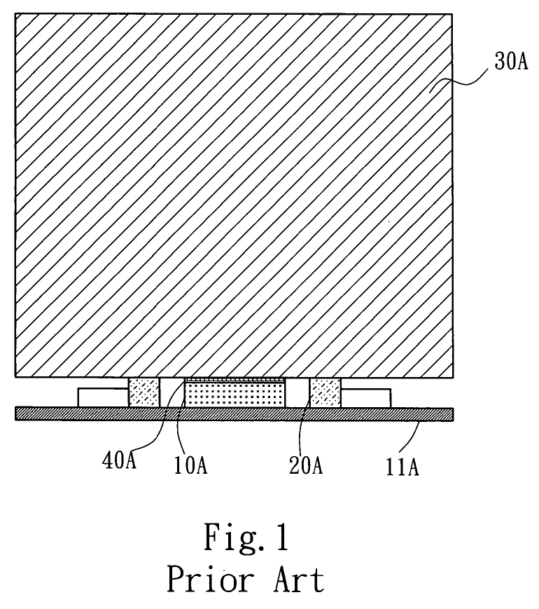

FIG. 2 is an exploded perspective view of the present invention;

FIG. 3 is a plan view of an assembly of FIG. 2;

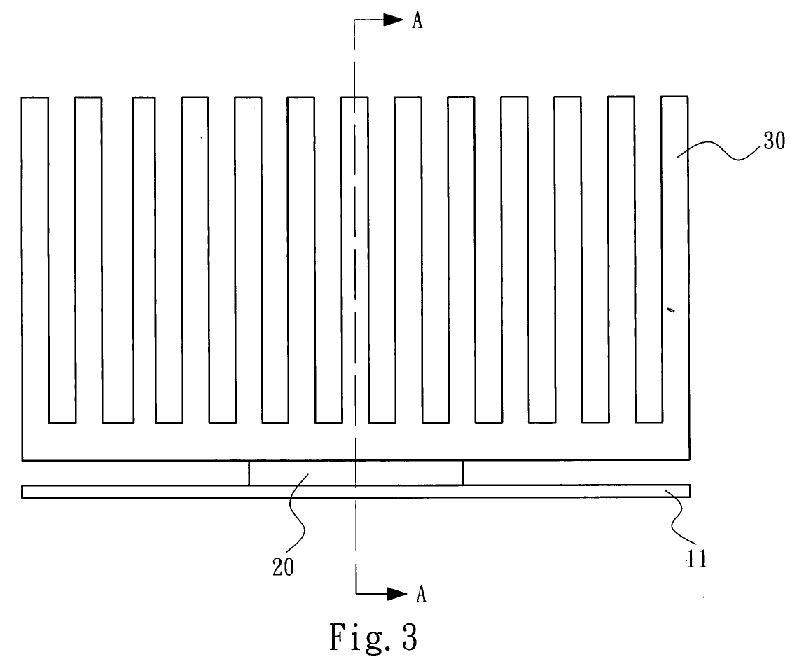

FIG. 4 is a cross sectional view taken on line A-A in FIG. 3 before changing phase;

FIG. 5 is another cross sectional view taken on line A-A in FIG. 3 after changing phase;

FIG. 6 is a cross sectional view of a second embodiment of the heat dissipating element;

FIG. 7 is a cross sectional view of a third embodiment of the heat dissipating element.

### DETAILED DESCRIPTION OF THE PREFFERED EMBODIMENT

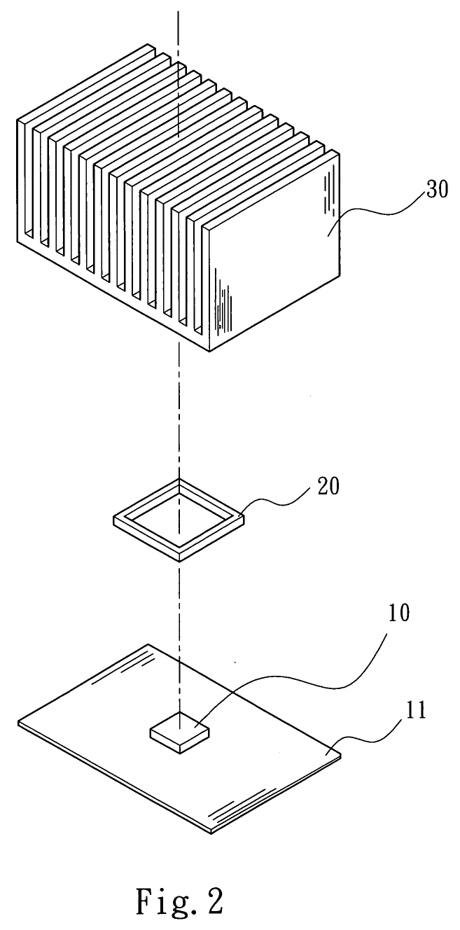

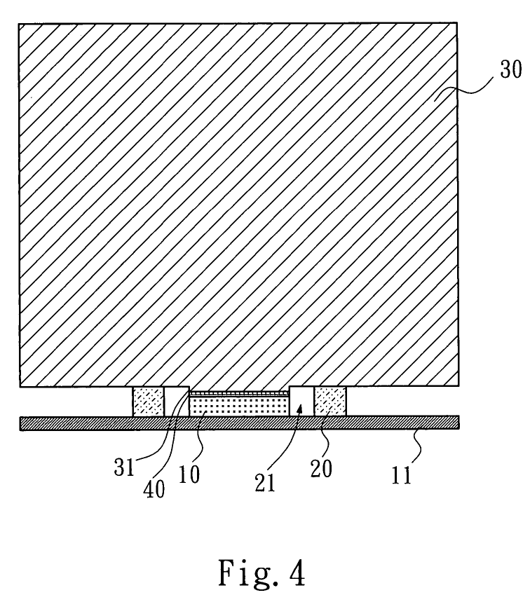

With reference to FIGS. 2˜5, a heat generating element (10) is wrapped around by a hollow isolating element (20) made of flexible and porous isolating material with a little larger dimension than that of the heat generating element (10). There is an interval (21) between an internal surface of the isolating element (20) and the heat generating element (10) to provide a receiving room for thermal interface material (40) coated between the heat generating element (10) and a heat dissipating element (30) to flow within the isolating element (20) while the thermal interface material (40) changes its solid phase to gel or liquid phase (as shown in FIG. 4).

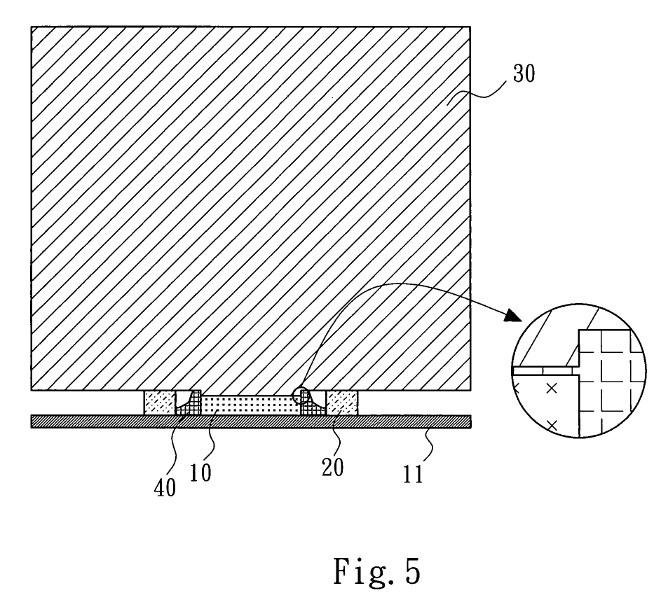

A bump (31) is formed on the bottom face of the heat dissipating element (30) to contact the heat generating element (10). The heat dissipating element (30) is assembled on the heat generating element (10) with a fastening device (known as prior art and not shown in the figures). The fastening device provide a fixing force to enhance that the heat dissipating element (30) is applying a force onto the isolating element (20) such that the isolating element (20) is able to be lengthened appropriately due to the flexibility, and the bump (31) of the heat dissipating element (30) is able to contact the heat generating element (10) with the thermal interface material (40) between them. Due to the applied force on the isolating element (20), the isolating element (20) is tightly sandwiched between a bottom surface of the heat dissipating element (30) and a surface of an circuit board (11) so there is no gap existing among the circuit board (11), the isolating element (20) and the heat dissipating element (30). Since the bump (31) is able to contact the heat generating element (10) after the heat dissipating element (30) compresses the isolating element (20), deformation of the isolating element (20) is limited. As shown in FIG. 5, while the thermal interface material (40) changes phase caused by the gradual rising temperature in the heat generating element (10) and overflows from the gap between the bump (31) and the heat generating element (10), the thermal interface material (40) will be blocked by the isolating element (20). Furthermore, due to the porosity of the isolating element (20) the vapor originally remaining in the thermal interface material (40) can flow through the isolating element (20) with the rising temperature so as to keep the tight contact of the isolating element (20) with heat dissipating element (30) and the circuit board (11). Accordingly, the overflow problem in prior arts is solved more effectively and thus, the contamination and short circuits do not no longer exist.

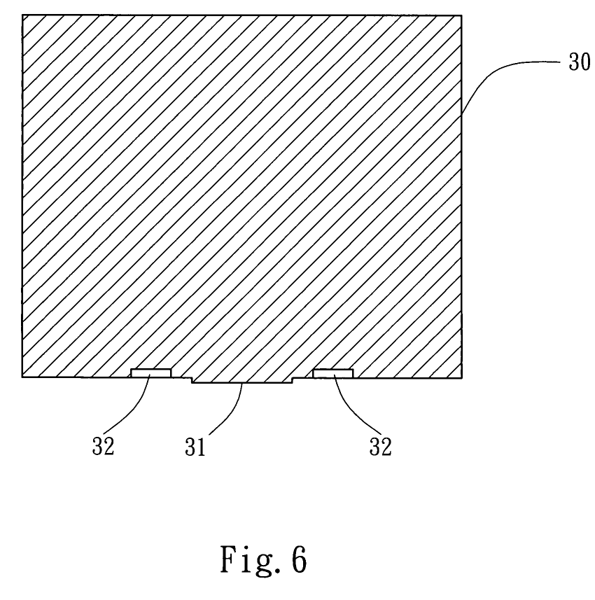

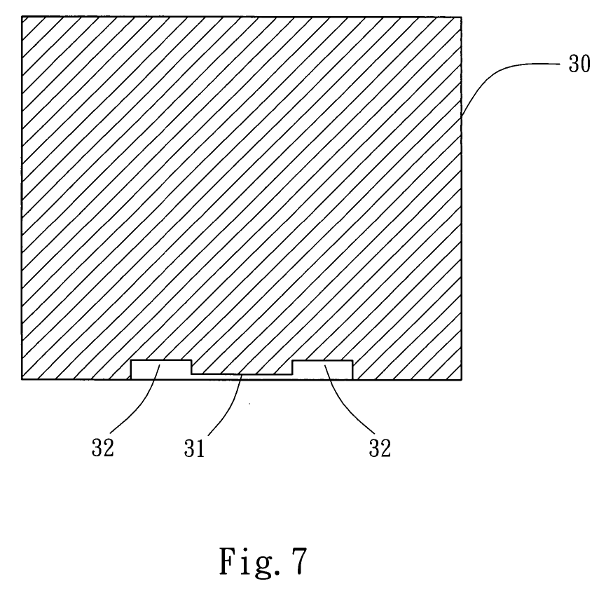

FIG. 6 is a second embodiment of the heat dissipating element. A recess (32) is defined in the bottom face of the heat dissipating element (30) and around the bump (31). The isolating element (20) is able to be received inside the recess (32). The bump (31) has the functions of reducing deformation of the isolating element (20) and transmitting heat from the heat generating element (10) to the heat dissipating element (30). As for the shape and pattern of the bottom face of the heat dissipating element (30), it is not the focus of the present invention, detailed description thereof is omitted. The heat dissipating element (30) can be in the manner as shown in FIG. 7. The recess (32) is defined in the bottom face of the heat dissipating element (30) and the bump (31) is formed on a bottom surface of the recess (32). Although the bump (31) presents a convex manner with respective to the bottom surface of the recess (32), it does not present the convex manner with respective to the bottom face of the heat dissipating element (30).

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

1. A structure for isolating thermal interface material, comprising:
an isolating element that is hollow and provided around a heat generating element;
a heat dissipating element contacting the isolating element and having a bump formed on one face thereof and contacting the heat generating element with thermal interface material between them to absorb heat generated by the heat generating element, the thermal interface material being limited to flow within a encompassed room defined between the isolating element and the heat generating element.

2. The structure for isolating thermal interface material of claim 1, wherein the bump is able to contact the heat generating element after the heat dissipating element contacts the heat generating element so as to prevent the isolating element from being overly compressed by the heat dissipating element.

3. The structure for isolating thermal interface material of claim 2, wherein the isolating element is able to encompass the bump.

4. The structure for isolating thermal interface material of claim 1, wherein the isolating element is made of flexible material.

5. The structure for isolating thermal interface material of claim 4, wherein the isolating element is made of porous material.

6. The structure for isolating thermal interface material of claim 1, wherein the dimension and height of the isolating element is larger than that of the heat generating element.

7. The structure for isolating thermal interface material of claim 1, wherein a recess is defined in the face of heat dissipating element and around the bump to receive the isolating element therein.

8. The structure for isolating thermal interface material of claim 1, wherein the thermal interface material changes its solid phase to liquid phase with respect to temperature change in the heat generating element.

9. The structure for isolating thermal interface material of claim 1, wherein the thermal interface material changes its solid phase to gel phase with rising temperature in the heat generating element.

10. The structure for isolating thermal interface material of claim 1, wherein the heat generating element is an electronic component.
